(19) United States
(12) Patent Application Publication
(10) Pub. No.: US 2003/0020456 A1
(43) Pub. Date: Jan. 30, 2003

(54) Hardened process controller

(76) Inventors: Grant William Ayo, Houston, TX (US); David Eric Hanson, Katy, TX (US); Mark Alan Payne, Houston, TX (US)

Correspondence Address: Alan R. Thiele, JENKENS & GILCHRIST, P.C., Suite 3200, 1445 Ross Avenue, Dallas, TX, 75202-2799, US

(21) Appl. No.: 10/190,939

(22) Filed: Jul. 8, 2002

Related U.S. Application Data
(60) Provisional application No. 60/303,533, filed on Jul. 6, 2001.

(51) Int. Cl. G01R 1/04

(52) U.S. Cl. 324/156

(57) ABSTRACT

A hardened process controller is encapsulated within a block of translucent material. Changes in the way the process controller transforms electrical input signals are effected by sending an optical signal through a portion of the translucent block to an optical receiver also encapsulated within the block of translucent material. Included within the block of translucent material is a digital display and electrical componentry selected for low heat output.

This patent application claims the benefit of U.S. Provisional Patent Application 60/303,533 filed Jul. 6, 2001.

### FIELD

The present invention pertains to process controllers or electrical devices including a digital display which provide a readout of electrical signals representative of a process condition. More particularly, the present invention pertains to encapsulated hardened process controllers suitable for use when placed in harsh environments or when there is an expectation of rough handling.

### BACKGROUND

In many environments, process controllers are used with electrical sensors and electrical control systems to monitor process parameters and where needed provide outputs. The outputs from the process controllers report on various conditions within the process or activate an alarm procedure if desired ranges for process parameters are exceeded. Such process controllers typically include a digital display of a key operational parameter which may or not be readable directly from an individual sensor physically located on the processing equipment—for example, flow rate. The displayed operational parameter is typically obtained from multiple electrical signals which are combined one with another by a variety of mathematical operations performed by electrical componentry within the process controller to produce a desired output.

Many of the operational conditions to which process controllers are exposed are quite harsh. For example, such harsh environments may be characterized by high temperatures, high moisture content, or chemical fumes such as often found in a chemical processing facility. In addition, process controllers are often subjected to rough handling or installed where heavy equipment is frequently moved around. In such environments it is not uncommon for process controllers to experience severe shock or vibratory loading. One example of a rough handling environment is that typically found at an oil well. Many conventional process controllers are not sealed to the environment or protected from shock or vibratory loading. These conventional process controllers will cease operations when subjected to harsh environments or rough handling.

U.S. Pat. No. 5,184,064 to the same assignee and included herein by reference describes a programmable indicator suitable for use in harsh environments or subjected to rough handling.

Attempts to expand the capabilities of the wireless externally programmable process controller described in U.S. Pat. No. 5,184,064 were limited because the heat generated by the components necessary to expand capabilities while maintaining wireless programmability could not be dissipated by the encapsulating material. Thus, the heat generated during operation simply caused key components to burn up within the encapsulating material. A variety of solutions for managing the heat were attempted such as finding a heat dissipating encapsulating material or including heat sinks to draw the heat away from sensitive components. Accordingly, it was felt by many of ordinary skill in the art that wireless programmable process controllers with expanded capabilities could not be built because of the problems associated with managing the heat build up of sensitive electrical components. Therefore, the need remained in the art for an expanded capability hardened process controller including encapsulated electrical componentry and a digital display which provides for wireless external programming of the encapsulated electrical componentry and a digital display to alter the way the encapsulated electrical componentry processes electrical signals received from the electrical sensors which monitor the process conditions.

### SUMMARY

Disclosed herein is an expanded capability hardened process controller with encapsulated electrical componentry and digital display which provides for externally programming the encapsulated electrical componentry to alter the way the encapsulated electrical componentry processes electrical signals received from electrical sensors which monitor process conditions. All of the electrical componentry is selected for its low heat output during operation.

Specifically, the hardened process controller of the present invention includes an input connection for receiving one or more electrical signals from sensors placed at predetermined locations on processing equipment. Electrically connected to the input connection is an electrical system for processing the input signals. This electrical system transforms the electrical signals received at the input connection to different electrical signals available at an output connection. To visually monitor a selected aspect, a digital display is included.

Because of the need to change or modify the manner in which the encapsulated electrical componentry transform the input signals, an optical receiver is included with the electrical componentry so that a programming signal from a source external to the encapsulated electrical componentry, such as an infra-red signal generator, may be used to change the way in which the electrical componentry transforms the input signals.

All of the low heat output electrical componentry, including the digital display and the optical receiver, are completely encapsulated in a hardened block of translucent material, preferably a translucent epoxy. The digital display is positioned so that it may be seen through the translucent block. Similarly, the optical receiver is positioned so that it may receive optical signals through the translucent block.

Also extending from the hardened process controller is an output connection which provides signals that have been transformed by the electrical componentry, which componentry has been programmed from an external source.

### BRIEF DESCRIPTION OF THE DRAWING FIGURES

A better understanding of the hardened process controller of the present invention may be had by reference to the drawing figures, wherein:

FIG. 1 is a front perspective view of the hardened process controller; and

FIG. 2 is a rear elevational view of the process controller shown in FIG. 1.

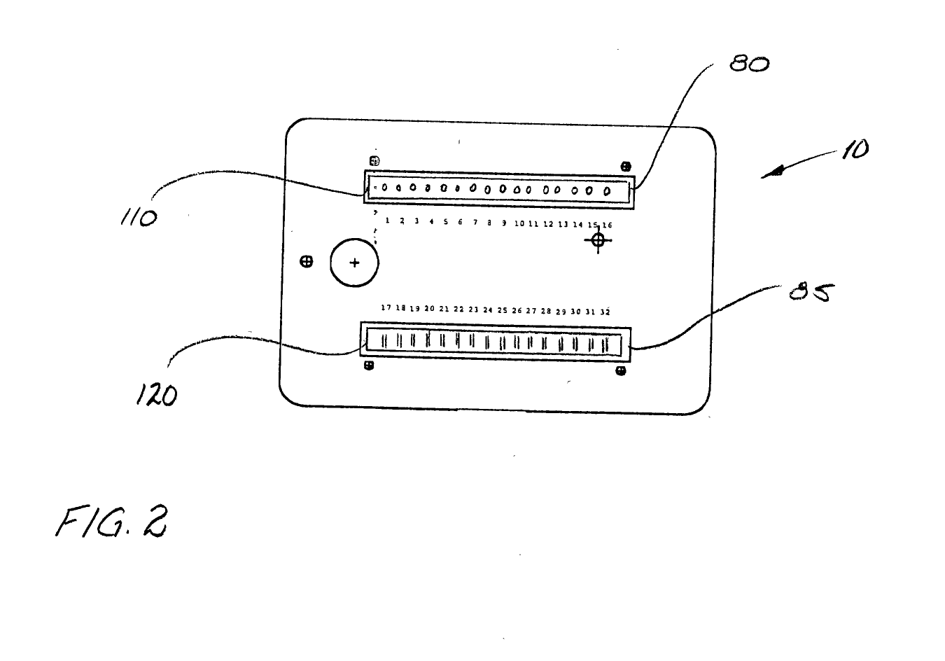

### DESCRIPTION OF THE EMBODIMENTS

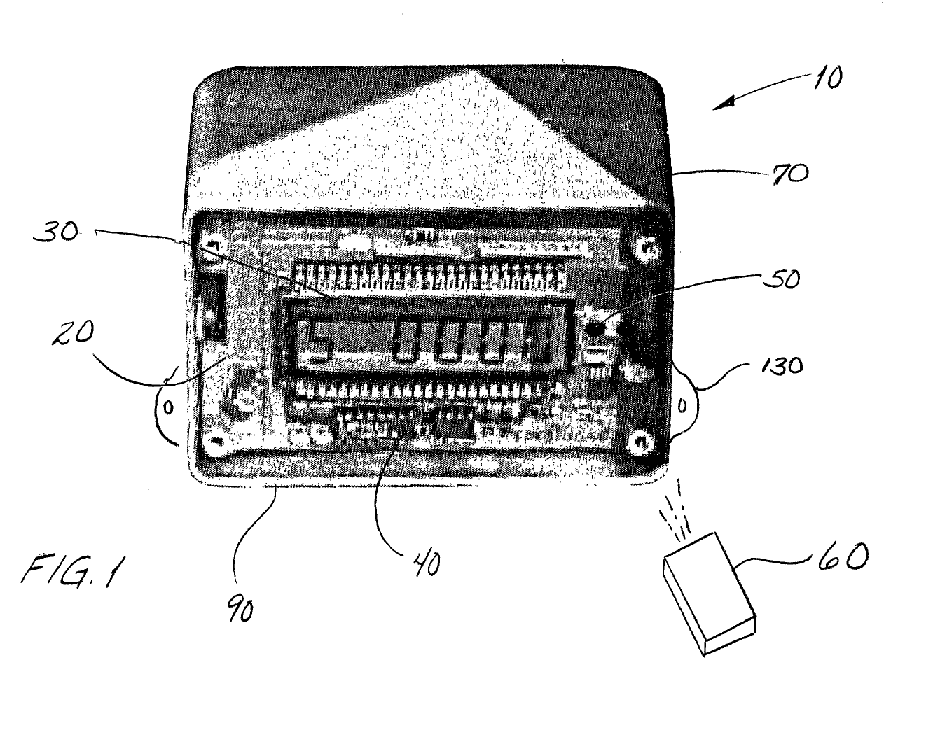

The hardened process controller 10 of the present invention is designed for use in harsh environments or in environments characterized by rough handling. Such environments include, for example, chemical processing facilities and oil wells. Accordingly, the electrical componentry of the process controller must be protected against the harsh environments or rough handling. Such protection is provided by encapsulating the electrical componentry in a hardened block of material 20 such as epoxy. If the process controller 10 includes a digital display 30, the epoxy selected for encapsulating the electrical componentry must be sufficiently translucent to read the digital display 30. As shown in FIG. 1, the hardened process controller 10 of the present invention includes electrical componentry 40 encapsulated within a block 20 of hardened epoxy to protect the electrical componentry 40 from harsh environments or rough handling.

As may be further seen in FIG. 1, the hardened process controller 10 of the present invention also includes an optical receiver 50 for receiving wireless programming signals to alter the way in which the electrical componentry 40 processes input signals. For example, hand held devices 60 such as a Palm Pilot® emit an infra-red signal when being used to program other devices. This infra-red signal will pass through the translucent epoxy block 20 to provide an input to the optical receiver 50. This input may then be used to modify the way in which the input signals are processed by the electrical componentry 40 within the hardened process controller 10. While optical signals such as infra-red are used in the preferred embodiment, any other signal which are transmittable through the encapsulating material 20 such as ultra-sound may be used. Of course, if ultra-sound signals are used, the optical receiver 50 would be replaced with a sound receiver which would enable wireless re-programming of the encapsulated electrical componentry 40.

The communication of the encapsulated electrical componentry 40 may be two-way, that is, the electrical componentry may not only be able to receive programming signals, but will be able to verify the receipt of such programming signals and the completion of the changes that have been made to the way in which the electrical componentry 40 processes signals. Such confirmation would be receivable by the programming device 60. Still further flexibility may be provided by encapsulating a rechargeable battery along with the electrical componentry 40. If a rechargeable battery is included, an external signal or a solar panel may be used to recharge the battery; or, alternatively, a solar panel could be encapsulated together with the electrical componentry if the process controller is exposed to light.

As indicated above, the capabilities of a wireless programmable hardened process controller 10 wherein the electrical componentry was sealed within a block of material so that each component was surrounded by epoxy were thought to be limited because of the problems associated with heat generation. Specifically, most epoxy materials do not readily dissipate heat so that individual electrical components become hotter and hotter during operation and eventually burn up. In non-encapsulated process controllers, a variety of heat dissipation systems are typically used. Such heat dissipation systems include increased air flow, positioning of high heat components apart from each other, and the creation of elaborate heat sinks or structures to draw heat away from high heat output components. Because of the need for total encapsulation of each and every electrical component, increased air flow around the electrical components was not a solution. Further, because of size limitations, positioning of the high heat electrical components apart from one another was also not a solution. Finally, the use of heat sinks or structures to draw the heat away from high heat output components for release into the atmosphere or areas of lower temperature was also impractical because any heat sinks also needed to be encapsulated. The discovery which enabled the creation of the expanded capability hardened process controller of the present invention was that operability could not be enhanced by dissipating heat as in prior art process controllers, but rather operability could be enhanced by limiting the generation of damaging heat. The problem of limiting the generation of heat was solved by selecting electrical componentry not only for its ability to adequately process electrical signals but also for its lower heat output. Typically, such individual items of electrical componentry which exhibit low heat output also have very low power requirements. It was found that if individual electrical components were selected whose increase in temperature was substantially less than about 10° C. over ambient temperature in operating conditions, such individual items of electrical componentry could be encapsulated and would not generate enough heat to self-destruct.

The flexibility provided by the realization that the selection of low heat output electrical componentry enabled the construction of a hardened process controller with wireless programming capabilities expanded the realm of electrical componentry that could be encapsulated in the block of material surrounding the components. For example, it was found that a 20 MHz microprocessor could be included along with sufficient memory to record input signals, interim calculations based on the input signals, or output signals. In addition, a solar cell or rechargeable battery may be encapsulated along with the electrical componentry.

The construction of the hardened process controller of the present invention begins with an assessment of the input signals to be received and the desired range of outputs. Depending on the application, the user will typically specify some type of firmware to be programmed into a microprocessor encapsulated within the process controller. This firmware will be programmed to receive input signals from one or more sensors monitoring various process conditions and transforming the sensed signals into another electrical signal needed for controlling the process being monitored. The process controller 10 will typically perform a mathematical operation on the electrical signal received from a sensor, to include combining one or more signals together according to a predetermined algorithm. However, it may be necessary to change the algorithm by which the signals are processed. Such changes are made by including a wireless programming capability which will receive change signals and cause these change signals to modify the imbedded algorithm by which input signals are processed, recorded or displayed. Usually the end product of the electrical componentry is a stack of several small circuit boards for mounting the necessary capacitors, resistors, transformers, resistors, transistors, or whatever else is needed to support the microprocessor including the firmware needed by the user. As previously indicated, each electrical component is selected for its low heat output. A determination is also made as to what type of mechanical connection will be made to the stack of small circuit boards imbedded in the hardened process controller. Most operations use some type of standard plug with either pin or blade connections. In particularly harsh applications, this connection may be a water-proof or sealed connector. If external electrical power is required, such connections should provide for power to be supplied to the hardened process controller 10.

With all of the electrical componentry arranged on a stack of small circuit boards, the stack of small circuit boards with an input connector and an output connector, a digital display, and an optical receiver are positioned within a metal container 70. The metal container 70 will include a first port 80 for the input connector, a second port 85 for the output connector, and a third port or an open side 90 to allow viewing of the digital display 30 and light signal impingement on the optical receiver 50.

The metal container is then filled with the encapsulating material 20. In the preferred embodiment, a translucent epoxy is poured into the metal container 20. Other translucent materials which will eventually harden around each and every electrical component may be used, such as some liquid glasses. Once the encapsulating material 20 fills the metal container 70, the process controller 10 is set aside to allow the encapsulating material to harden. As shown in FIG. 1, the preferred embodiment includes an open side 90 through which the digital display meter 30 may be observed and through which the process controller 10 may be optically programmed. On the back are included the input 110 and output 120 connections. The metal container 70 which is used as a mold for the hardenable material may be left on to provide further protection or to provide the mechanical connections 130 needed to mount the process controller 10 in a display panel.

Because of the flexibility provided by the hardened process controller 10 of the present invention, it has been found that the disclosed hardened process controllers may be networked with a variety of other process control equipment to include other process controllers—hardened or unhardened. Testing has revealed that the hardened process controller 10 of the present invention will operate satisfactorily in environments having temperatures as low as about −30° C. and as hot as about 70° C. While the hardened process controllers 10 of the present invention provide a readout through the encapsulated digital display 30, they may also be used to break a circuit, illuminate a light, sound a horn, or flash a particular digital display if a certain process parameter has been exceeded. By using the wireless programmability, the range of process parameters which trigger another event may be adjusted to suit the particular process to which the hardened process controller 10 of the present invention is attached.

While the present invention has been described according to its preferred and alternate embodiments, those of ordinary skill in the art will understand that still other numerous other embodiments have been enabled by the foregoing disclosure. Such other embodiments shall be included within the scope and meaning of the appended claims.

What is claimed is:

1. A hardened electrical process controller comprising:
a first connection for receiving one or more electrical input signals;
means for processing said one or more electrical input signals including externally programmable, low heat output electrical componentry;
a digital display connected to said means for processing said one or more electrical input signals;
a second connection for producing one or more electrical output signals from said means for processing said one or more electrical input signals; and
a translucent block formed around said digital display and said electrical componentry.

2. The hardened electrical process controller as defined in claim 1 further including a metallic case formed around said translucent block, said metallic case including a first port for said first connection, a second port for said second connection, and a third port for said digital display.

3. The hardened electrical process controller as defined in claim 1 wherein said externally programmable, low heat output electrical componentry includes an optical receiver for receiving optical signals which alter the way said means for processing said one or more electrical input signals operates.

4. The hardened electrical process controller as defined in claim 3 wherein said optical receiver is constructed and arranged to receive infra-red signals.

5. The hardened electrical process controller as defined in claim 1 further including a battery which is rechargeable through said translucent block.

6. The hardened electrical process controller as defined in claim 1 wherein said externally programmable low heat electrical componentry increase in temperature no more than about 10° C. above ambient temperature while operating.

7. The hardened electrical process controller as defined in claim 1 further including a memory for recording one or more of said input signals, calculated values based on said input signals, or said output signals.

8. A process control system comprising:
a plurality of sensors constructed and arranged to provide electrical signals representative of process conditions;
at least one hardened process controller for receiving and processing said electrical signals representative of process conditions;
a display panel for mounting said at least one hardened process controller;
each of said hardened process controllers including:
a first connection for receiving said signals representative of process conditions;
externally programmable, low heat output electrical componentry for processing said signals representative of process conditions;
a second connection for providing electrical signals from said externally programmable, low heat output electrical componentry;
means for providing a digital display connected to said externally programmable, low heat output electrical componentry; and
a translucent block formed to encapsulate said externally programmable, low heat output electrical componentry.

9. The process control system as defined in claim 8 further including means for networking said at least one hardened process controller to other process controllers.

10. The process controller as defined in claim 8 wherein said externally programmable, low heat output electrical componentry includes an optical receiver for receiving optical signals which alter the way in which said electrical componentry processes said signals representative of operating conditions.

11. The process controller as defined in claim 10 wherein said optical receiver is constructed and arranged to receive infra-red signals.

12. The process controller as defined in claim 8 wherein said translucent block is formed of epoxy.

13. The process controller as defined in claim 8 wherein said externally programmable, low heat output electrical componentry increases in temperature no more than about 10° C. during operation.

14. The process controller as defined in claim 8 wherein said electrical componentry further includes a memory whose contents may be accessed through said digital display or said second connection.

15. A method of making a hardened process controller comprising the steps of:
forming a metal case including a first port for receiving a first electrical connector, a second port for receiving a second electrical connector, and a third port for a digital display;
constructing an externally programmable, signal processing electrical system from substantially low heat output electrical components wherein said electrical components includes at least a first electrical connector, a second electrical connector, and a digital display;
inserting said externally programmable, signal processing electrical system into said metal case so that said first electrical connector passes through said first port, said second electrical connector passes through said second port, and said digital display is readable through said third port;
filling said metal case with a hardenable translucent material to encapsulate said signal processing system in said hardenable translucent material;
allowing said hardenable translucent material to harden.

16. The method as defined in claim 15 wherein said externally programmable, signal processing system further includes an optical receiver constructed and arranged to receive optical signals through said hardened translucent material.

17. The method as defined in claim 16 wherein said optical receiver is further constructed and arranged to receive infra-red signals.

18. The method as defined in claim 15 wherein said externally programmable, signal processing system further includes a memory for storing information about electrical signals.

19. The method as defined in claim 15 wherein said substantially low heat electrical components are selected from a group of electrical components which have less than a substantially 10° C. increase in temperature when operating.

20. The method as defined in claim 15 wherein said hardenable translucent material is epoxy.
